(19) United States
(12) Patent Application Publication
(10) Pub. No.: US 2026/0305173 A1
(43) Pub. Date: Oct. 1, 2026

(54) METHOD FOR MANUFACTURING ARRAY SENSOR ELEMENT AND ARRAY SENSOR ELEMENT

(71) Applicant: SEIKO EPSON CORPORATION, Tokyo (JP)

(72) Inventors: Takashi MIYATA, SHIOJIRI-SHI (JP); Manabu KUDO, SUWA-SHI (JP)

(73) Assignee: SEIKO EPSON CORPORATION, Tokyo (JP)

(21) Appl. No.: 19/577,393

(22) Filed: Mar. 25, 2026

(30) Foreign Application Priority Data
Mar. 27, 2025 (JP) 2025-053396

(51) Int. Cl. H10N 30/071; H10N 30/06; H10N 30/30; H10N 39/00

(52) U.S. Cl. CPC H10N 30/071; H10N 30/06; H10N 30/302; H10N 39/00

(57) ABSTRACT

A method for manufacturing an array sensor element includes: (a) depositing an exfoliation film on a first substrate; (b) depositing a passivation film on the exfoliation film; (c) forming piezoelectric elements in an array on the passivation film, the piezoelectric elements each having a first electrode layer, a piezoelectric layer, and a second electrode layer laminated on each other; (d) placing a second substrate over the piezoelectric elements and bonding an element layer including the piezoelectric elements to the second substrate; and (e) irradiating a surface of the first substrate with laser light, the surface being opposite a surface on which the exfoliation film is deposited, and a high-melting-point metal layer is deposited as the first electrode layer when the first electrode layer is a single layer and is deposited as a lowermost layer of the first electrode layer when the first electrode layer has multiple layers.

The present application is based on, and claims priority from JP Application Serial Number 2025-053396, filed Mar. 27, 2025, the disclosure of which is hereby incorporated by reference herein in its entirety.

### BACKGROUND

### 1. Technical Field

The present disclosure relates to a method for manufacturing an array sensor element, and the array sensor element.

### 2. Related Art

As a detection apparatus including elements arranged in an array, the elements each having a structure in which multiple thin films are laminated on each other, for example, an imaging apparatus described in JP-A-2010-231336, an ultrasonic device described in JP-A-2017-029270, and the like are known. The elements used in the detection apparatuses described above are form by using a technology for manufacturing a flat panel display. JP-A-2013-046086 discloses a method for manufacturing an ultrasonic array sensor.

JP-A-2010-231336, JP-A-2017-029270, and JP-A-2013-046086 are examples of the related art.

Attempts have been made to form the array sensor described above, for example, on a flexible substrate. For example, there is a method for forming a transferred layer including elements at a transfer body such as a flexible substrate by forming a resin layer on a substrate, forming the transferred layer on the resin layer, bonding the transferred layer to the transfer body, and then irradiating the resin layer with laser light to separate the substrate from the transferred layer. Since an electrode layer contained in the transferred layer is heated in the step of radiating the laser light in the method, hillocks may be generated.

### SUMMARY

According to an aspect of the present disclosure, a method for manufacturing an array sensor element is provided. The manufacturing method includes: (a) depositing an exfoliation film on a first substrate; (b) depositing a passivation film on the exfoliation film; (c) forming piezoelectric elements in an array on the passivation film, the piezoelectric elements each having a first electrode layer, a piezoelectric layer, and a second electrode layer laminated on each other; (d) placing a second substrate over the piezoelectric elements and bonding an element layer including the piezoelectric elements to the second substrate; and (e) irradiating a surface of the first substrate with laser light, the surface being opposite a surface on which the exfoliation film is deposited, to exfoliate the piezoelectric elements from the first substrate, and in (c), when the first electrode layer is a single layer, a high-melting-point metal layer is deposited as the first electrode layer, and when the first electrode layer has multiple layers, the high-melting-point metal layer is deposited as a lowermost layer of the first electrode layer.

### BRIEF DESCRIPTION OF THE DRAWINGS

FIG. 1 is a top view showing a schematic configuration of an array sensor element.

FIG. 2 is a cross-sectional view showing a cross-sectional structure of an example of a piezoelectric elements.

FIG. 3 is a flowchart showing the process of manufacturing the array sensor element.

FIG. 4 illustrates a laser light radiation method.

FIG. 5 illustrates a method for radiating laser light from a laser light radiator.

FIG. 6 shows results of evaluation of exfoliation.

### DESCRIPTION OF EMBODIMENTS

### A. Embodiment

### A1. Structure of array sensor element

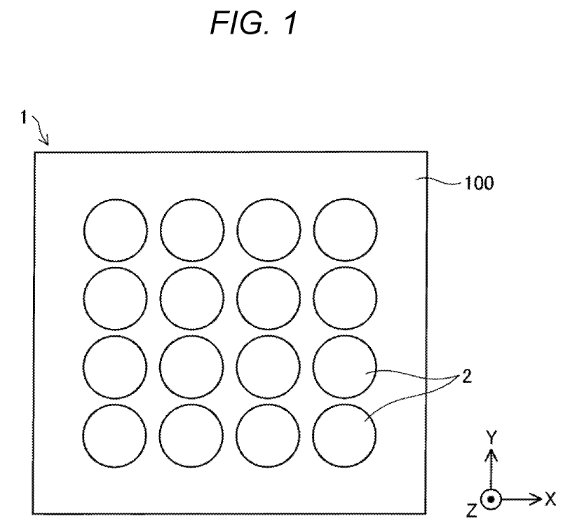

FIG. 1 is a top view showing a schematic configuration of an array sensor element 1. FIG. 1 shows arrows indicating X, Y, and Z directions orthogonal to one another. The X and Y directions are parallel to the horizontal plane. The Z direction is parallel to the vertical direction. The X, Y, and Z directions in FIG. 1 and the X, Y, and Z directions in the other figures indicate the same directions. A direction in which films such as an exfoliation film 20, which will be described later, are laminated on a glass substrate 10, which will be described later, is also called "upward".

The array sensor element 1 includes a sensor substrate 100 as a second substrate, and multiple piezoelectric elements 2 arranged in an array on the sensor substrate 100. FIG. 1 shows an example of the array sensor element 1 including 16 piezoelectric elements 2. In the example shown in FIG. 1, the piezoelectric elements 2 are arranged in a 4×4 array along the X and Y directions. Note that the piezoelectric elements 2 may be arranged in accordance with what is called a staggered pattern, in which the piezoelectric elements 2 are alternately arranged in the X direction or the Y direction. The number of the piezoelectric elements 2 provided in the array sensor element 1 is not limited to 16.

The sensor substrate 100 is a transparent substrate. The sensor substrate 100 can, for example, be a substrate made of synthetic resin such as polyethylene, or a glass substrate made, for example, of silicate glass. A flexible substrate that is bendable may be used as the sensor substrate 100. The sensor substrate 100 has the shape of a quadrangular plate. Note that the sensor substrate 100 may have the shape of a circular, elliptical, or polygonal plate instead of the shape of a quadrangular plate.

The piezoelectric elements 2 each have a structure in which multiple thin films each including electrodes are laminated on each other. The piezoelectric elements 2 each include a first electrode layer 140, a piezoelectric layer 150, and a second electrode layer 160, which will be described later.

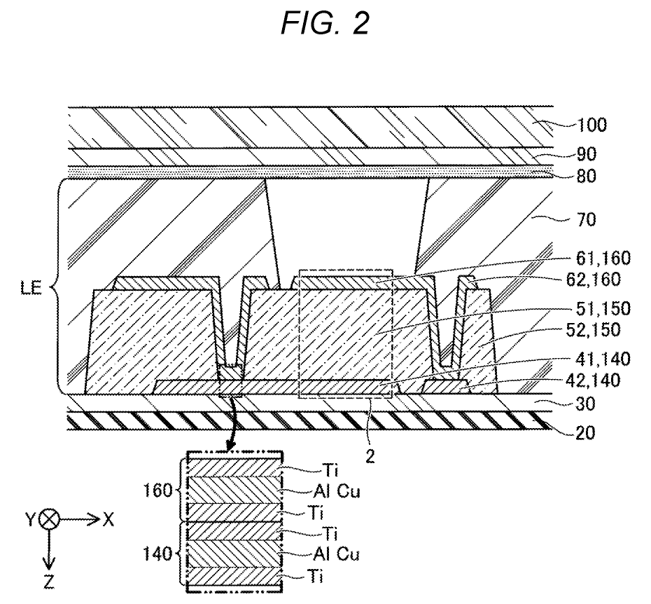

FIG. 2 is a cross-sectional view showing a cross-sectional structure of an example of each of the piezoelectric elements 2. The layers formed on the sensor substrate 100 are formed on the glass substrate 10 as a first substrate described later in a manufacturing process described later, and then transferred to the sensor substrate 100, as will be described later. The layers will be described in the order of deposition of the films on the glass substrate 10 described later, that is, from the lower side toward the upper side in the plane of view of FIG. 2.

The exfoliation film 20 is a layer to be exfoliated from the glass substrate 10 when the layers are transferred to the sensor substrate 100. In the present embodiment, the exfoliation film 20 is a polyimide film. As another form, the exfoliation film 20 may be made of another synthetic resin, for example, polyethylene terephthalate (PET).

A passivation film 30 is formed on the exfoliation film 20. In the present embodiment, the passivation film 30 is a laminated film configured with a silicon nitride film and a silicon oxide film laminated on each other in this order.

A first electrode 41 and a first electrode wire 42 are formed on the passivation film 30. The first electrode 41 and the first electrode wire 42 are formed by depositing the first electrode layer 140 and then patterning the first electrode layer 140 in the manufacturing process, which will be described later. In the description, the first electrode 41 is an electrode that constitutes the piezoelectric element 2 and is used to detect an external force applied to a piezoelectric layer 50 in the present embodiment. The first electrode wire 42 is a wire used to couple the first electrode 41 to a terminal that is not shown but is formed at the sensor substrate 100. Hereinafter, when the first electrode 41 and the first electrode wire 42 are not distinguished from each other, they are also called the first electrode layer 140.

In the present embodiment, the first electrode 41 and the first electrode wire 42 have a laminated structure. The lowermost layer of the first electrode 41 and the uppermost layer of the first electrode 41 are high-melting-point metal layers. The high-melting-point metal layer contains at least one substance selected from the group including titanium (Ti) and molybdenum (Mo). In the present embodiment, the high-melting-point metal layer is a titanium layer. Specifically, in the present embodiment, the first electrode 41 and the first electrode wire 42 are each a laminated film made of titanium, aluminum-copper alloy (AlCu), and titanium laminated in this order on each other. Aluminum copper alloy (AlCu) has low resistance and is suitable as a material for electrodes and wires. The melting point of titanium is higher than the melting point of aluminum-copper alloy. The configuration in which the titanium layer is provided as the lowermost layer of the first electrode 41 can therefore suppress generation of hillocks when the laminated film is irradiated with laser light, as will be described later in detail. In addition, the configuration in which the titanium layer, which is a high-melting-point metal layer, is provided as the uppermost layer of the first electrode 41 can suppress electromigration resulting from application of a voltage to the space between the first electrode 41 and a second electrode 61 during use of the array sensor element 1.

A piezoelectric element region 51 and a piezoelectric dummy region 52 are formed on the first electrode 41 and the first electrode wire 42. The piezoelectric element region 51 and the piezoelectric dummy region 52 are formed by depositing the piezoelectric layer 150 and then patterning the piezoelectric layer 150 in the manufacturing process. In the description, the piezoelectric element region 51 is a region that constitutes the piezoelectric element 2 and is used to detect the applied external force in the present embodiment. The piezoelectric dummy region 52 is a region formed for height adjustment for reducing film unevenness, reduction in etching unevenness in the patterning, and the like. Hereinafter, when the piezoelectric element region 51 and the piezoelectric dummy region 52 are not distinguished from each other, they are also called the piezoelectric layer 150.

In the present embodiment, the piezoelectric layer 150 is made of crystalline aluminum nitride (AlN). As another embodiment, the piezoelectric layer 150 may be made of a metal compound other than aluminum nitride, a composite oxide such as lead zirconate titanate (PZT), or the like.

The second electrode 61 and a second electrode wire 62 are formed on the piezoelectric element region 51 and the piezoelectric dummy region 52. The second electrode 61 and the second electrode wire 62 are formed by depositing the second electrode layer 160 and then patterning the second electrode layer 160 in the manufacturing process. The second electrode wire 62 is a wire used to couple the second electrode 61 to a terminal that is not shown but is formed at the sensor substrate 100. Hereinafter, when the second electrode 61 and the second electrode wire 62 are not distinguished from each other, they are also called the second electrode layer 160.

To electrically couple the first electrode layer 140 to the second electrode layer 160, there is a portion where the piezoelectric layer 150 between the first electrode layer 140 and the second electrode layer 160 is removed, as shown in FIG. 2. The portion where the piezoelectric layer 150 between the first electrode layer 140 and the second electrode layer 160 is removed is also called a contact portion.

In the present embodiment, the second electrode layer 160 has a laminated structure. The lowermost layer of the second electrode layer 160 contains at least one substance selected from the group including titanium and molybdenum. In the present embodiment, the lowermost layer of the second electrode layer 160 is a titanium layer. An increase in contact resistance of a portion where the first electrode layer 140 and the second electrode layer 160 are in contact with each other can thus be suppressed, as will be described later in detail.

The uppermost layer of the second electrode layer 160 contains at least one substance selected from the group including titanium, molybdenum, and tungsten (W). In the present embodiment, the uppermost layer of the second electrode layer 160 is a titanium layer. The accuracy of patterning a planarization film 70 formed on the second electrode layer 160 can thus be improved, as described later in detail.

In the present embodiment, the second electrode layer 160 is a laminated film made of titanium, aluminum-copper alloy (AlCu), and titanium laminated in this order on each other. Aluminum copper alloy (AlCu) has low resistance and is suitable as a material for electrodes and wires.

The planarization film 70, an adhesive layer 80, and a protective layer 90 are sequentially formed on the second electrode 61. The planarization film 70 is a film containing a photosensitive resin. In the present embodiment, the planarization film 70 is a negative-type photosensitive resin. In the present embodiment, the protective layer 90 is a silicon nitride film.

The laminated structure from the first electrode 41 to the planarization film 70 is called an element layer LE below. The element layer LE includes the piezoelectric element 2.

### A2. Method for manufacturing array sensor element

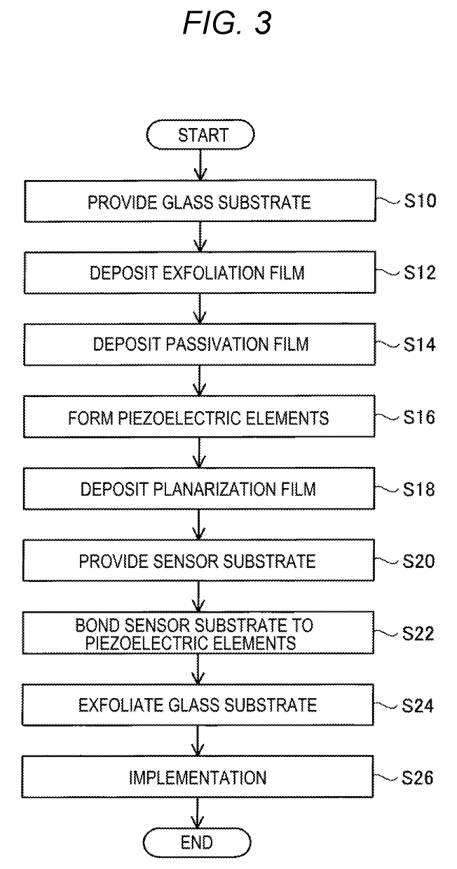

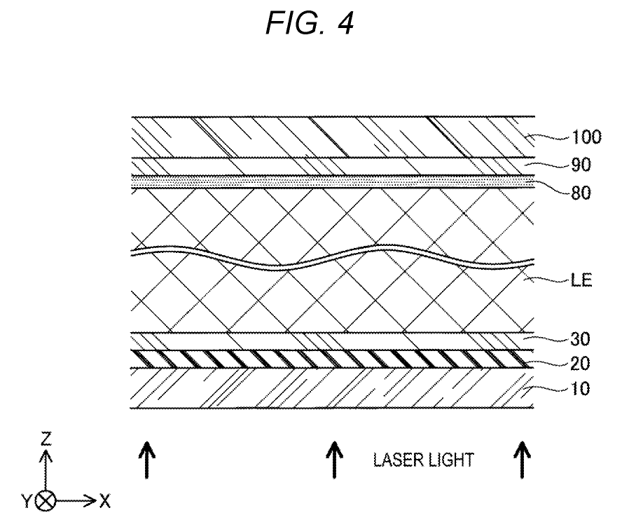

FIG. 3 is a flowchart showing the process of manufacturing the array sensor element 1. A method for manufacturing the array sensor element 1 is realized by carrying out the manufacturing process. In step S10, the glass substrate 10 shown in FIG. 4, which will be described later, is provided, as shown in FIG. 3. The glass substrate 10 is a transparent substrate. In the present embodiment, an alkali-free glass substrate is used as the glass substrate 10. The piezoelectric elements 2 are formed on the glass substrate 10. The glass substrate 10 is therefore preferably a substrate that is unlikely to deteriorate in the process of manufacturing the piezoelectric elements 2. Specifically, the glass substrate 10 is preferably a substrate that is unlikely to deteriorate due to heating conditions in the manufacturing process or radiation of laser light. Since the sensor substrate 100 contained in the array sensor element 1 is not used in the process of manufacturing the piezoelectric elements 2, the sensor substrate 100 may not be unlikely to deteriorate in the manufacturing process. The material of the sensor substrate 100 can therefore be selected with increased flexibility by using a material of the glass substrate 10 used in the manufacturing process different from the material of the sensor substrate 100 contained in the array sensor element 1. Furthermore, when the glass substrate 10 is more expensive than the sensor substrate 100, the manufacturing cost of the array sensor element 1 can be reduced by reusing the glass substrate 10.

In step S12 in FIG. 3, the exfoliation film 20 is deposited on the glass substrate 10. Specifically, the exfoliation film 20 is deposited by applying a liquid polyimide precursor onto the glass substrate 10 in spin coating and then sintering the polyimide precursor. In the present embodiment, the film thickness of the exfoliation film 20 is greater than or equal to about 3 μm but smaller than or equal to about 15 μm.

In step S14, the passivation film 30 is deposited. Specifically, a silicon nitride film and a silicon oxide film are sequentially deposited on the exfoliation film 20 by using plasma chemical vapor deposition (CVD).

In step S16, the piezoelectric elements 2 are formed. Specifically, the first electrode 41 and the first electrode wire 42 are first formed. In detail, after the first electrode layer 140 is formed by sputtering, patterning using a photolithography technology is performed. In detail, a titanium film, an aluminum-copper alloy film, and a titanium film are sequentially deposited in the step of depositing the first electrode layer 140.

The piezoelectric element region 51 and the piezoelectric dummy region 52 are then formed. In detail, after the piezoelectric layer 150 is deposited by sputtering, patterning using a photolithography technology is performed.

The second electrode 61 and the second electrode wire 62 are then formed. In detail, after the second electrode layer 160 is deposited by sputtering, patterning using a photolithography technology is performed. In detail, a titanium film, an aluminum-copper alloy film, and a titanium film are sequentially deposited in the step of depositing the second electrode layer 160.

As described above, the array sensor element 1 has the contact portion, which is the portion where the piezoelectric layer 150 between the first electrode layer 140 and the second electrode layer 160 is removed. The present embodiment, in which the uppermost layer of the first electrode layer 140 is a titanium layer and the lowermost layer of the second electrode layer 160 is a titanium layer, allows suppression of an increase in contact resistance of the contact portion, where the first electrode layer 140 and the second electrode layer 160 are in contact with each other.

In the steps before the step of depositing the second electrode layer 160, the first electrode layer 140 is exposed to the atmosphere in some cases. If the lowermost layer of the second electrode layer 160 is an aluminum layer, oxygen and aluminum at the exposed surface of the first electrode layer 140 bond to each other to produce aluminum oxide when the aluminum layer is deposited. Since aluminum oxide is an insulator, the presence of aluminum oxide increases the contact resistance of the portion where the first electrode layer 140 and the second electrode layer 160 are in contact with each other. If the uppermost layer of the first electrode layer 140 is an aluminum layer, aluminum oxide is similarly produced at the exposed surface of the first electrode layer 140, which causes an increase in the contact resistance. In this regard, the present embodiment, in which the uppermost layer of the first electrode layer 140 is a titanium layer and the lowermost layer of the second electrode layer 160 is a titanium layer, allows suppression of an increase in the contact resistance of the portion where the first electrode layer 140 and the second electrode layer 160 are in contact with each other.

In step S18, the planarization film 70 is deposited. In detail, after a photosensitive resin is applied, for example, by spin coating, the photosensitive resin is exposed to light by using a photomask, and then developed to form a desired pattern of the photosensitive resin. In the present embodiment, the uppermost layer of the second electrode layer 160 is a titanium layer. Since titanium has a relatively low reflectance for light for exposure, the amount of light reflected off the titanium layer in the exposure step is relatively small. The accuracy of patterning the planarization film 70 can therefore be improved. The wavelength of the light for exposure is, for example, longer than or equal to about 10 nm but shorter than or equal to about 400 nm.

In step S20, the sensor substrate 100 is provided. In step S20, the protective layer 90 and the adhesive layer 80 are sequentially formed at the provided sensor substrate 100.

In step S22, the sensor substrate 100 is placed on the piezoelectric element 2, and the piezoelectric element 2 and the sensor substrate 100 are bonded to each other.

In step S24, a surface of the glass substrate 10 that is the surface opposite the surface at which the exfoliation film 20 has been deposited is irradiated with laser light, so that the glass substrate 10 is exfoliated from the element layer LE. In detail, after the laser light radiation, the glass substrate 10 is exfoliated from the element layer LE by applying an external force in a way that the glass substrate 10 is separated from the element layer LE. In the present embodiment, after the glass substrate 10 is exfoliated, a portion of the exfoliation film 20 remains at the lower surface of the element layer LE.

FIG. 4 illustrates a laser light radiation method in step S24. The glass substrate 10 is irradiated with laser light from below, as shown in FIG. 4. The radiated laser light passes through the glass substrate 10 and reaches the exfoliation film 20. The exfoliation film 20 is thus removed by the laser light. It is presumed that the removal of the exfoliation film 20 is caused by dissolution of a portion of the exfoliation film 20 and transformation of the exfoliation film 20 into a gas that occur when energy is supplied to the exfoliation film 20 to break inter-atom bonds in the polyimide and release the atoms or molecules. In the present embodiment, excimer laser light is used as the laser light. As another embodiment, the laser light may be light output from a solid-state laser and having a wavelength of 355 nm.

The disclosers have found a problem of hillocks that are likely to be generated at the lowermost layer of the first electrode 41 in step S24 when the lowermost layer is made of aluminum-copper alloy, unlike in the present embodiment. It is believed that this is because the heat generated in the process of supplying the exfoliation film 20 with the radiated laser light is transferred to the first electrode 41. It is also believed that about 90% of the radiated laser light is absorbed by the exfoliation film 20. The disclosers have found that the generation of hillocks can be suppressed by using a high melting point metal layer as the lowermost layer of the first electrode 41.

Furthermore, as a result of studying the conditions of the laser light to be radiated, the disclosers have found that the substrate can be satisfactorily exfoliated while suppressing the generation of hillocks by setting the energy density of the laser light to a value greater than 80 mJ/cm² but smaller than 100 mJ/cm² and setting the total amount of the energy density of the laser light to be radiated to a unit region of the substrate to a value greater than 450 mJ/cm².

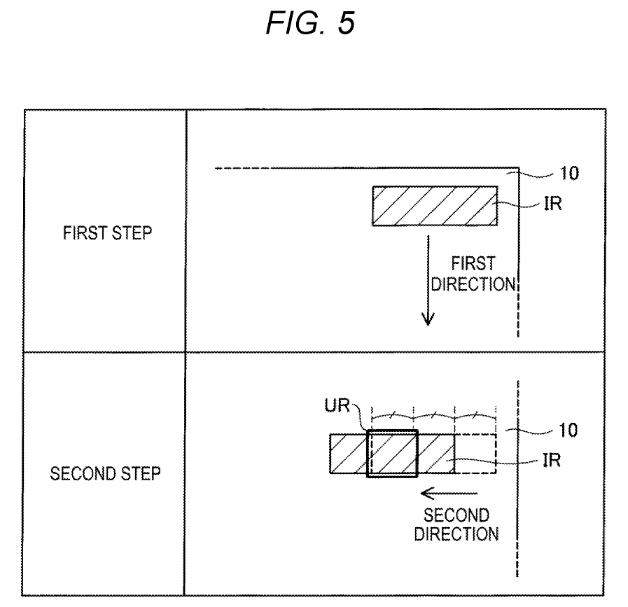

In the present embodiment, the laser light is excimer laser light from an excimer laser using xenon as rare gas atoms and chlorine as halogen atoms. The wavelength of the laser light is 308 nm. A laser light radiator used in the present embodiment is what is called a line-beam apparatus that irradiates a rectangular irradiated region IR (FIG. 5) with the laser light.

FIG. 5 illustrates a method for radiating laser light from the laser light radiator used in the present embodiment. In the radiation method, first and second steps are repeatedly carried out. In the first step, the laser light is so radiated that the irradiated region IR of the glass substrate 10 irradiated with the laser light is moved from a start point to an end point along a first direction, as shown in FIG. 5. In the second step, the irradiated region IR is moved in a second direction perpendicular to the first direction. When the amount of movement in the second direction is set shorter than the length of the irradiated region IR in the second direction, a unit region UR of the glass substrate 10 is irradiated with the laser light multiple times at temporal intervals.

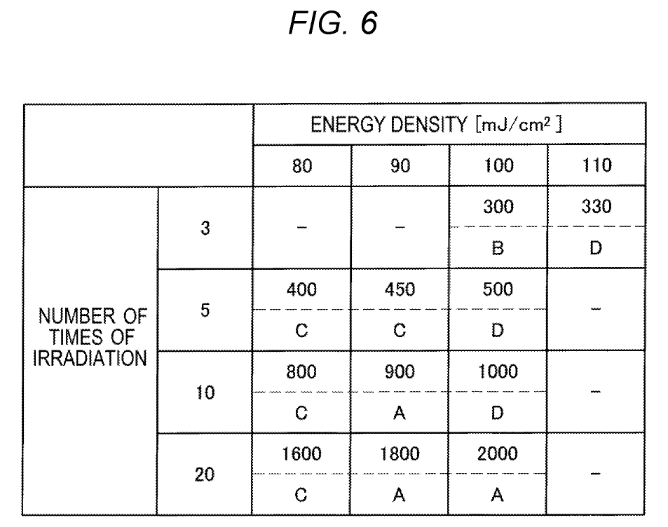

FIG. 6 shows results of evaluation in which the exfoliation of the element layer LE is evaluated with the laser conditions changed. The laser conditions in the evaluation are all so set that the unit region UR is irradiated with the laser light multiple times at temporal intervals. The "number of times of radiation" in the table shown in FIG. 6 is the number of times the unit region UR is irradiated with the laser light at temporal intervals.

Criteria of the evaluation shown in FIG. 6 are as follows:
A: The exfoliation was satisfactorily achieved.
B: The exfoliation was not satisfactorily achieved.
C: The exfoliation was not successfully achieved.
D: The exfoliation was successfully achieved, but the piezoelectric elements were broken.

The evaluation result "A" indicates a state in which the bonding force that bonds the exfoliation film 20 and the glass substrate 10 to each other is sufficiently reduced, so that the element layer LE can be readily exfoliated from the glass substrate 10. The evaluation result "B" indicates a state in which the bonding force that bonds the exfoliation film 20 and the glass substrate 10 to each other is reduced, so that the element layer LE can be exfoliated from the glass substrate 10 without being damaged by applying an external force. The evaluation result "C" indicates a state in which the bonding force that bonds the exfoliation film 20 and the glass substrate 10 to each other remains, so that the element layer LE cannot be exfoliated from the glass substrate 10. The evaluation result "D" indicates a state in which damage, for example, to the first electrode layer 140, the second electrode layer 160, or the planarization film 70 can be ascertained. In the state of the evaluation result "D", it is believed that the films are damaged because the energy supplied by the laser light is too large.

In each field in FIG. 6, the numeral described above the alphabetic letter representing the evaluation result is the total amount of the energy density of the laser light with which the unit region UR of the substrate is irradiated. The total amount of the energy density is calculated by multiplying the energy density of the laser light by the number of times of the radiation.

When the energy density of the laser light is set to a value greater than 80 mJ/cm² but smaller than 100 mJ/cm², and the total amount of the energy density of the laser light with which the unit region UR of the glass substrate 10 is irradiated is set to a value greater than 450 mJ/cm², satisfactory exfoliation can be achieved, as shown in FIG. 6. The results shown in FIG. 6 show that when the laser light radiated each time has a large energy density, the piezoelectric elements 2 are broken, whereas when the laser light radiated each time has a small energy density, the exfoliation cannot be achieved. The results further show that exfoliation cannot also be achieved when the total amount of the energy density of the laser light is small. The findings described above show that the energy density of the laser light is preferably greater than 80 mJ/cm² but smaller than 100 mJ/cm², and the total amount of the energy density of the laser light irradiated to the unit region UR of the glass substrate 10 is preferably greater than 450 mJ/cm². The findings further show that the energy density of the laser light is more preferably 90 mJ/cm², and the total amount of the energy density of the laser light irradiated to the unit region UR of the substrate is more preferably greater than or equal to 900 mJ/cm².

Step S26 in FIG. 3 is an implementation step of electrically coupling a terminal formed at the sensor substrate 100 to an external instrument, the implementation step being used for electrical coupling to the piezoelectric elements 2. Specifically, in the implementation step, for example, when the sensor substrate 100 is coupled to the external instrument via a printed circuit board, the terminal formed at the sensor substrate 100 is electrically coupled to a terminal formed at the printed circuit board by wire bonding. For example, when the sensor substrate 100 is coupled to the external instrument via flexible printed circuits (FPC), the terminal formed at the sensor substrate 100 is bonded to a terminal formed at the flexible printed circuits. The element layer LE is electrically coupled to the external instrument by carrying out step S26. When step S26 ends, the manufacturing process ends.

According to the embodiment described above, the process of manufacturing the array sensor element 1 includes steps S12, S14, S16, S22, and S24. In step S12, the exfoliation film 20 is deposited on the glass substrate 10. In step S14, the passivation film 30 is deposited on the exfoliation film 20. In step S16, the piezoelectric elements 2, in each of which the first electrode layer 140, the piezoelectric layer 150, and the second electrode layer 160 are laminated on each other, are formed in an array on the passivation film 30. In step S22, the sensor substrate 100 is placed on the piezoelectric elements 2, and the piezoelectric elements 2 and the sensor substrate 100 are bonded to each other. In step S24, to exfoliate the piezoelectric elements 2 from the glass substrate 10, the laser light is radiated toward a surface of the glass substrate 10 that is the surface opposite the surface at which the exfoliation film 20 has been deposited. In step S16, a high-melting-point metal layer is deposited as the lowermost layer of the first electrode layer 140. In the present embodiment, a titanium layer is deposited as the high-melting-point metal layer. Titanium is unlikely to generate hillocks. Therefore, even when the laser light is radiated in step S24, generation of hillocks at the first electrode layer 140 can be suppressed.

The uppermost layer of the first electrode layer 140 is a high-melting-point metal layer. In the present embodiment, a titanium layer is deposited as the high-melting-point metal layer. Titanium is unlikely to cause electromigration. Electromigration during use of the array sensor element 1 can be therefore suppressed. A titanium layer is deposited as the lowermost layer of the second electrode layer 160. Therefore, even if titanium oxide is produced in the manufacturing process, an increase in the contact resistance of the portion where the first electrode layer 140 and the second electrode layer 160 are in contact with each other can be suppressed because the titanium oxide is not an insulator. The uppermost layer of the second electrode layer 160 is a titanium layer. Therefore, in the exposure step of forming the planarization film 70, the reflection of the light for exposure off the second electrode layer 160 is suppressed, so that the accuracy of patterning the planarization film 70 can be improved.

In step S24, the first step of irradiating the laser light in a way that the irradiated region IR irradiated with the laser light is moved from the start point to the end point along the first direction, and the second step of moving the irradiated region IR in the second direction are repeatedly carried out. The energy density of the excimer laser light irradiated to the unit region UR is greater than 80 mJ/cm² but smaller than 100 mJ/cm², and the total amount of the energy density of the excimer laser light irradiated to the unit region UR is greater than 450 mJ/cm². The piezoelectric elements 2 can thus be satisfactorily exfoliated without breakage thereof.

### B. Other embodiments

(B1) In the embodiment described above, the lowermost layer of the first electrode layer 140 is a titanium layer. In another embodiment, the lowermost layer of the first electrode layer 140 may be a molybdenum layer. Molybdenum is also unlikely to generate hillocks, and can therefore suppress generation of hillocks due to the radiation of the laser light. The lowermost layer of the first electrode layer 140 may be made of an alloy containing titanium or an alloy containing molybdenum. Even when an alloy containing titanium or an alloy containing molybdenum is used, the generation of hillocks due to the radiation of the laser light can be suppressed. The first electrode layer 140 may be a single layer made of titanium or a single layer made of molybdenum.

(B2) In the embodiment described above, the uppermost layer of the first electrode layer 140 is a titanium layer. In another embodiment, the uppermost layer of the first electrode layer 140 may be a molybdenum layer. Molybdenum is also unlikely to cause electromigration, and can therefore suppress the occurrence of electromigration. The uppermost layer of the first electrode layer 140 may be made of an alloy containing titanium or molybdenum. Even when an alloy containing titanium or molybdenum is used, the occurrence of electromigration can be suppressed.

(B3) In the embodiment described above, the lowermost layer of the second electrode layer 160 is a titanium layer. In another embodiment, the lowermost layer of the second electrode layer 160 may be a molybdenum layer. Since molybdenum oxide is also not an insulator, an increase in the contact resistance of the portion where the first electrode layer 140 and the second electrode layer 160 are in contact with each other can be suppressed. The lowermost layer of the second electrode layer 160 may be made of an alloy containing titanium or an alloy containing molybdenum. Even when an alloy containing titanium or an alloy containing molybdenum is used, an increase in the contact resistance of the portion where the first electrode layer 140 and the second electrode layer 160 are in contact with each other can be suppressed. The second electrode layer 160 may be a single layer made of titanium or a single layer made of molybdenum.

(B4) In the embodiment described above, the uppermost layer of the second electrode layer 160 is a titanium layer. In another embodiment, the uppermost layer of the second electrode layer 160 may be a molybdenum layer or a tungsten layer. Since a molybdenum layer and a tungsten layer also reflect light for exposure at relatively low reflectance, the accuracy of patterning the planarization film 70 can be improved. In the embodiment described above, a negative-type photosensitive resin is used for the planarization film 70. As another embodiment, a positive-type photosensitive resin may be used for the planarization film 70.

### C. Other aspects

The present disclosure is not limited to the embodiments described above, and can be implemented in various aspects without departing from the intent of the present disclosure. For example, the present disclosure can also be implemented in the following aspects. The technical features in the embodiments described above corresponding to the technical features in the aspects described below can be replaced with other technical features or combined with each other as appropriate to solve some or all of the problems of the present disclosure, or achieve some or all of the advantages of the present disclosure. The technical features can be deleted as appropriate unless described as being essential in the present specification.
(1) According to a first aspect of the present disclosure, a method for manufacturing an array sensor element is provided. The manufacturing method includes:
   (a) depositing an exfoliation film on a first substrate;
   (b) depositing a passivation film on the exfoliation film;
   (c) forming piezoelectric elements in an array on the passivation film, the piezoelectric elements each having a first electrode layer, a piezoelectric layer, and a second electrode layer laminated on each other;
   (d) placing a second substrate over the piezoelectric elements and bonding an element layer including the piezoelectric elements to the second substrate; and
   (e) irradiating a surface of the first substrate with laser light, the surface being opposite a surface on which the exfoliation film is deposited, to exfoliate the piezoelectric elements from the first substrate, and in (c), when the first electrode layer is a single layer, a high-melting-point metal layer is deposited as the first electrode layer, and when the first electrode layer has multiple layers, the high-melting-point metal layer is deposited as a lowermost layer of the first electrode layer. This aspect, in which the first electrode layer is a single high-melting-point metal layer or the lowermost layer of the first electrode layer is a high-melting-point metal layer allows suppression of generation of hillocks at the first electrode layer due to the radiation of laser light in step (e).
(2) In the aspect described above, the high-melting-point metal layer may contain at least one substance selected from the group including titanium and molybdenum.
(3) In the aspect described above, the first electrode layer may have the multiple layers, and in (c), the high-melting-point metal layer may be deposited as an uppermost layer of the first electrode layer. According to this aspect, the high-melting-point metal is unlikely to cause electromigration, so that electromigration can be suppressed during use of the array sensor element.
(4) In the aspect described above, the uppermost layer of the first electrode layer may contain at least one substance selected from the group including titanium and molybdenum, and in (c), when the second electrode layer is a single layer, a layer containing at least one substance selected from the group including titanium and molybdenum may be deposited as the second electrode layer, and when the second electrode layer has multiple layers, a layer containing at least one substance selected from the group including titanium and molybdenum may be deposited as a lowermost layer of the second electrode layer. According to this aspect, when the array sensor element has a structure in which the first electrode layer and the second electrode layer are in contact with each other, an increase in contact resistance of the portion where the first electrode layer and the second electrode layer are in contact with each other can be suppressed even if titanium oxide or molybdenum oxide is produced at the first electrode layer or the second electrode layer in the manufacturing process because the titanium oxide and the molybdenum oxide are not insulators.
(5) In the aspect described above, the manufacturing method may include (f) depositing, after (c), a photosensitive resin on the second electrode layer, the second electrode layer may have the multiple layers, and in (c), a layer containing at least one substance selected from the group including titanium, molybdenum, and tungsten may be deposited as an uppermost layer of the second electrode layer. According to this aspect, titanium, molybdenum, and tungsten reflect light for exposure at relatively low reflectance, so that the accuracy of patterning the photosensitive resin can be improved.
(6) In the aspect described above, in (e) described above, a first step of irradiating the first substrate with the laser light in a way that an irradiated region of the first substrate irradiated with the laser light is moved from a start point to an end point along a first direction and a second step of moving the irradiated region in a second direction perpendicular to the first direction may be repeatedly carried out to irradiate a unit region of the first substrate with the laser light multiple times at temporal intervals, an energy density of the laser light irradiated to the unit region may be greater than 80 mJ/cm² but smaller than 100 mJ/cm², and a total amount of the energy density of the laser light irradiated to the unit region may be greater than 450 mJ/cm². According to this aspect, the piezoelectric elements can be satisfactorily exfoliated without breakage thereof.
(7) In the aspect described above, the energy density may be 90 mJ/cm², and the total amount of the energy density may be greater than or equal to 900 mJ/cm². According to this aspect, the piezoelectric elements can be more satisfactorily exfoliated without breakage thereof.
(8) According to a second aspect of the present disclosure, an array sensor element is provided. The array sensor element includes: an exfoliation film; a passivation film formed on the exfoliation film; and piezoelectric elements formed on the passivation film and arranged in an array, the piezoelectric elements each having a first electrode layer, a piezoelectric layer, and a second electrode layer laminated on each other, the first electrode layer is configured with a single layer or multiple layers, and when the first electrode layer is the single layer, the first electrode layer includes a high-melting-point metal layer, and when the first electrode layer is configured with the multiple layers, a lowermost layer of the first electrode layer includes the high-melting-point metal layer. According to this aspect, the first electrode layer is a single high-melting-point metal layer or the lowermost layer of the first electrode layer is a high-melting-point metal layer, so that an array sensor element having the first electrode layer with no hillock generation or reduced hillock generation can be provided.

What is claimed is:

1. A method for manufacturing an array sensor element, the method comprising:
(a) depositing an exfoliation film on a first substrate;
(b) depositing a passivation film on the exfoliation film;
(c) forming piezoelectric elements in an array on the passivation film, the piezoelectric elements each having a first electrode layer, a piezoelectric layer, and a second electrode layer laminated on each other;
(d) placing a second substrate over the piezoelectric elements and bonding an element layer including the piezoelectric elements to the second substrate; and
(e) irradiating a surface of the first substrate with laser light, the surface being opposite a surface on which the exfoliation film is deposited,
wherein a high-melting-point metal layer is deposited as the first electrode layer when the first electrode layer is a single layer and is deposited as a lowermost layer of the first electrode layer when the first electrode layer has multiple layers.

2. The method for manufacturing the array sensor element according to claim 1, wherein
the high-melting-point metal layer contains at least one substance selected from the group including titanium and molybdenum.

3. The method for manufacturing the array sensor element according to claim 1, wherein
the first electrode layer has the multiple layers, and
the high-melting-point metal layer is deposited as an uppermost layer of the first electrode layer.

4. The method for manufacturing the array sensor element according to claim 3, wherein
the uppermost layer of the first electrode layer contains at least one substance selected from the group including titanium and molybdenum, and
when the second electrode layer is a single layer, a layer containing at least one substance selected from the group including titanium and molybdenum is deposited as the second electrode layer, and when the second electrode layer has multiple layers, a layer containing at least one substance selected from the group including titanium and molybdenum is deposited as a lowermost layer of the second electrode layer.

5. The method for manufacturing the array sensor element according to claim 4, comprising
(f) depositing, after (c) described above, a photosensitive resin on the second electrode layer,
wherein the second electrode layer has the multiple layers, and
a layer containing at least one substance selected from the group including titanium, molybdenum, and tungsten is deposited as an uppermost layer of the second electrode layer.

6. The method for manufacturing the array sensor element according to claim 1, wherein
in (e) described above, a first step of irradiating the first substrate with the laser light in a way that an irradiated region of the first substrate irradiated with the laser light is moved from a start point to an end point along a first direction and a second step of moving the irradiated region in a second direction perpendicular to the first direction are repeatedly carried out to irradiate a unit region of the first substrate with the laser light multiple times at temporal intervals,
an energy density of the laser light irradiated to the unit region is greater than 80 mJ/cm² but smaller than 100 mJ/cm² and
a total amount of the energy density of the laser light irradiated to the unit region is greater than 450 mJ/cm².

7. The method for manufacturing the array sensor element according to claim 6, wherein
the energy density is 90 mJ/cm² and
the total amount of the energy density is greater than or equal to 900 mJ/cm².

8. An array sensor element comprising:
an exfoliation film;
a passivation film formed on the exfoliation film; and
piezoelectric elements formed on the passivation film and arranged in an array, the piezoelectric elements each having a first electrode layer, a piezoelectric layer, and a second electrode layer laminated on each other,
wherein the first electrode layer is configured with a single layer or multiple layers, and the first electrode layer includes a high-melting-point metal layer when the first electrode layer is the single layer and a lowermost layer of the first electrode layer includes the high-melting-point metal layer when the first electrode layer is configured with the multiple layers.
